(19) United States
(12) Patent Application Publication
(10) Pub. No.: US 2019/0155095 A1
(43) Pub. Date: May 23, 2019

(54) COLOR FILM SUBSTRATE AND METHOD FOR MANUFACTURING THE SAME, AND LIQUID CRYSTAL DISPLAY PANEL

(71) Applicant: Shenzhen China Star Optoelectronics Technology Co. Ltd., Shenzhen (CN)

(72) Inventors: Lixuan Chen, Shenzhen (CN); Xulin Lin, Shenzhen (CN); Liuyang Yang, Shenzhen (CN); Pei Jia, Shenzhen (CN)

(21) Appl. No.: 16/039,300

(22) Filed: Jul. 18, 2018

Related U.S. Application Data
(63) Continuation of application No. PCT/CN2018/092113, filed on Jun. 21, 2018.

(30) Foreign Application Priority Data
Nov. 22, 2017 (CN) 201711181323.5

(51) Int. Cl. G02F 1/1335; G02B 1/111; G02B 1/113; G02B 5/20

(52) U.S. Cl. CPC G02F 1/133516; G02F 1/133512; G02F 1/133502; H01L 27/1214; G02B 1/113; G02B 5/201; G02B 1/111

(57) ABSTRACT

The present disclosure discloses a color film substrate and a method for manufacturing the same as well as a liquid crystal display panel. The color film substrate includes: a substrate, a black matrix disposed on the substrate, and an antireflection layer disposed between the substrate and the black matrix. The refractive index of the antireflection layer is about 1.6˜2.0, and the thickness of the antireflection layer is greater than 100 nm; or the refractive index of the antireflection layer is about 1.5˜2.4, and the thickness of the antireflection layer is less than 60 nm. In the aforesaid way, the present disclosure can decrease the reflectance of the liquid crystal display panel in a simpler manner and at a lower cost, thereby improving the display quality of the liquid crystal display panel under the environment of strong light.

### CROSS-REFERENCE TO RELATED APPLICATIONS

The present application is a continuation application conversion of International (PCT) Patent Application No. PCT/CN2018/092113 filed Jun. 21, 2018, which claims foreign priority of Chinese Patent Application No. 201711181323.5, filed on Nov. 22, 2017 in the State Intellectual Property Office of China, the contents of all of which are hereby incorporated by reference.

### TECHNICAL FIELD

The present disclosure relates to the technical field of liquid crystal display, and more particularly, relates to a color film substrate and a method for manufacturing the same as well as a liquid crystal display panel.

### BACKGROUND

A liquid crystal display (LCD) panel has features such as a small volume, low power consumption and being non-radiative, and thus has become dominant in the display field. However, the conventional liquid crystal display panel does not have visibility outdoors or under environment of strong external light, so in this case it cannot be used normally.

To solve the aforesaid technical problem, a liquid crystal display panel of a low reflectance may be adopted to reduce the reflection of the ambient light at the surface of the display so that the actual contrast perceived by eyes of human under the environment of strong light is increased, thereby improving picture quality and effects.

FIG. 1 is a schematic structural view of a liquid crystal display panel of a low reflectance currently available. As shown in FIG. 1, the liquid crystal display panel comprises an array substrate 11, a color film substrate 12, and a liquid crystal layer 13 interposed between the array substrate 11 and the color film substrate 12. A side of a substrate 121 of the color film substrate 12 that is away from the liquid crystal layer 13 is attached with a polarizing plate 14, and the other side of the substrate 121 is sequentially provided with a black matrix 122 and a transparent conductive layer 123. The polarizing plate 14 is a polarizing plate that has subjected to surface treatment, and the reflectance thereof may be reduced to 0.1% or even lower than 0.1% from 4% as for a conventional polarizing plate, thereby lowering the reflectance of the whole liquid crystal display panel. However, since the polarizing plate 14 needs to be subjected to surface treatment, the cost of the polarizing plate 14 is multiplied. Each time the reflectance of the polarizing plate 14 is further reduced, the cost of the polarizing plate 14 will be increased, and this is unfavorable for cost control.

Accordingly, an urgent need exists in the art to decrease the reflectance of the liquid crystal display panel in a simpler manner and at a lower cost, thereby improving the display quality of the liquid crystal display panel under the environment of strong light.

### SUMMARY

A main technical problem to be solved by the present disclosure is to provide a color film substrate and a method for manufacturing the same as well as a liquid crystal display panel, which can decrease the reflectance of the liquid crystal display panel in a simpler manner and at a lower cost, thereby improving the display quality of the liquid crystal display panel under the environment of strong light.

To solve the aforesaid technical problem, one technical solution adopted by the present disclosure is to provide a color film substrate, and the color film substrate comprises: a substrate, a black matrix disposed on the substrate, and an antireflection layer disposed between the substrate and the black matrix; wherein a refractive index of the antireflection layer is about 1.6˜2.0, and the thickness of the antireflection layer is greater than 100 nm; or the refractive index of the antireflection layer is about 1.5˜2.4, and the thickness of the antireflection layer is less than 60 nm.

To solve the aforesaid technical problem, another technical solution adopted by the present disclosure is to provide a liquid crystal display panel, and the liquid crystal display panel comprises the aforesaid color film substrate, an array substrate disposed opposite to the color film substrate and a liquid crystal layer interposed between the color film substrate and the array substrate.

To solve the aforesaid technical problem, yet another technical solution adopted by the present disclosure is to provide a method for manufacturing a color film substrate, and the method comprises: forming an antireflection layer and a black matrix sequentially on the substrate; wherein a refractive index of the antireflection layer is about 1.6˜2.0, and the thickness of the antireflection layer is greater than 100 nm; or the refractive index of the antireflection layer is about 1.5˜2.4, and the thickness of the antireflection layer is less than 60 nm.

Benefits of the present disclosure are as follows: the color film substrate and the method for manufacturing the same as well as the liquid crystal display panel of the present disclosure can decrease the reflectance of the liquid crystal display panel in a simpler manner and at a lower cost and thereby improve the display quality of the liquid crystal display panel under the environment of strong light by providing the antireflection layer between the black matrix and the substrate of the color film substrate, wherein the refractive index of the antireflection layer is about 1.6˜2.0 and the thickness of the antireflection layer is greater than 100 nm; or the refractive index of the antireflection layer is about 1.5˜2.4 and the thickness of the antireflection layer is less than 60 nm.

### BRIEF DESCRIPTION OF THE DRAWINGS

FIG. 1 is a schematic structural view of a liquid crystal display panel of a low reflectance currently available.

FIG. 2 is a schematic structural view of a liquid crystal display panel according to an embodiment of the present disclosure.

FIG. 3 is a schematic structural view of a first embodiment of a color film substrate comprised in the liquid crystal display panel shown in FIG. 2.

FIG. 4 is a schematic view illustrating relationships between the thickness of an antireflection layer and energy of the reflected light when the refractive index of the antireflection layer is 1.5.

FIG. 5 is a schematic view illustrating relationships between the thickness of the antireflection layer and energy of the reflected light when the refractive index of the antireflection layer is 1.6.

FIG. 6 is a schematic view illustrating relationships between the thickness of the antireflection layer and energy of the reflected light when the refractive index of the antireflection layer is 1.7.

FIG. 7 is a schematic view illustrating relationships between the thickness of the antireflection layer and energy of the reflected light when the refractive index of the antireflection layer is 1.8.

FIG. 8 is a schematic view illustrating relationships between the thickness of the antireflection layer and energy of the reflected light when the refractive index of the antireflection layer is 1.9.

FIG. 9 is a schematic view illustrating relationships between the thickness of the antireflection layer and energy of the reflected light when the refractive index of the antireflection layer is 2.0.

FIG. 10 is a schematic view illustrating relationships between the thickness of the antireflection layer and energy of the reflected light when the refractive index of the antireflection layer is 2.4.

FIG. 11 is a schematic structural view of a second embodiment of the color film substrate comprised in the liquid crystal display panel shown in FIG. 2.

FIG. 12 is a flowchart diagram of a method for manufacturing a color film substrate according to a first embodiment of the present disclosure.

FIG. 13 is a flowchart diagram of a method for manufacturing a color film substrate according to a second embodiment of the present disclosure.

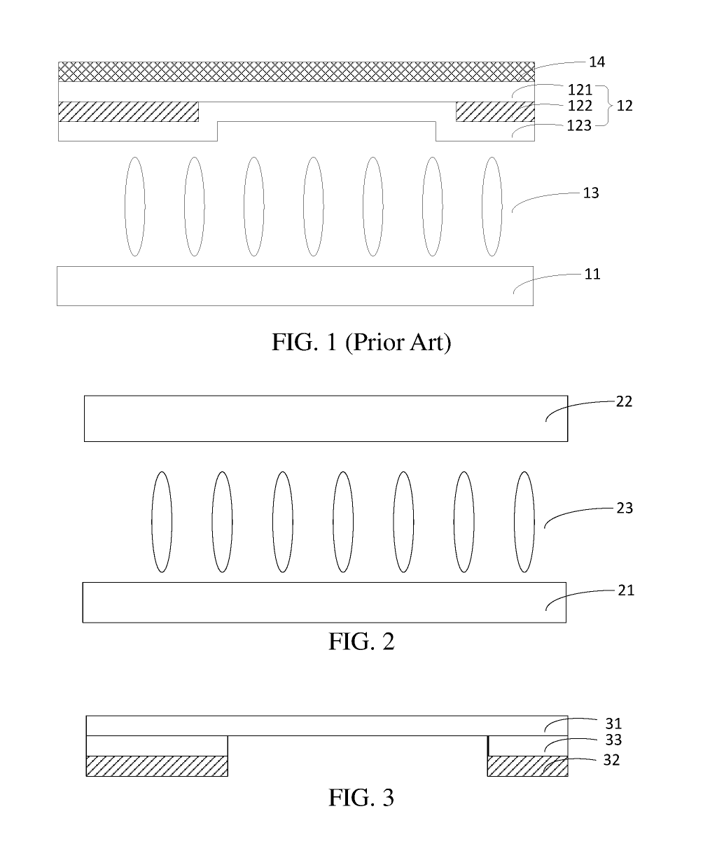

### DETAILED DESCRIPTION

Some vocabularies are used in the specification and the claims to refer to particular components, and as shall be appreciated by those skilled in the art, manufactures may use different terms to refer to the same components. The components are not distinguished by the difference of the terms used in the specification and the claims, and instead, the components are distinguished based on differences in functionalities thereof. Thereinafter, the present disclosure will be detailed with reference to the attached drawings and embodiments.

FIG. 2 is a schematic structural view of a liquid crystal display panel according to an embodiment of the present disclosure. As shown in FIG. 2, the liquid crystal display panel comprises an array substrate 21, a color film substrate 22 and a liquid crystal layer 23 interposed between the array substrate 21 and the color film substrate 22.

Referring to FIG. 3 together, FIG. 3 is a schematic structural view of a first embodiment of a color film substrate comprised in the liquid crystal display panel shown in FIG. 2. As shown in FIG. 3, the color film substrate 22 comprises a substrate 31, a black matrix 32 disposed on the substrate 31, and an antireflection layer 33 disposed between the substrate 31 and the black matrix 32. A refractive index of the antireflection layer 33 is about 1.6˜2.0, and the thickness of the antireflection layer 33 is greater than 100 nm; or the refractive index of the antireflection layer is about 1.5˜2.4, and the thickness of the antireflection layer is less than 60 nm.

In this embodiment, the antireflection layer 33 and the black matrix 32 have the same pattern, so whether the antireflection layer 33 is transparent or not is not limited in this embodiment.

In this embodiment, the refractive index of the antireflection layer 33 is smaller than a refractive index of the black matrix 32 and is greater than a refractive index of the substrate 31.

Optionally, the refractive index of the antireflection layer 33 satisfies the following equation:

max(G, (G*M)0.5−0.2)<C<min((G*M)0.5+0.2,M)

wherein G is a refractive index of the substrate 31, M is a refractive index of the black matrix 32, and C is the refractive index of the antireflection layer 33.

In this embodiment, there are three options for the material of the antireflection layer 33:
the antireflection layer 33 may be another black matrix that belongs to the same category as the black matrix 32 and has a refractive index lower than that of the black matrix 32. In other words, the antireflection layer 33 has the same composition as the black matrix 32, and the composition at least comprises carbon powders and polymers. In a mixed system of carbon powders and polymers, the equivalent refractive index increases as the content of the carbon powders increases, so the content of the carbon powders in the antireflection layer 33 is set to be smaller than the content of the carbon powders in the black matrix 32 so that the refractive index of the antireflection layer 33 is lower than the reflectance of the black matrix 32.
2. the material of the antireflection layer 33 may be an organic material, and the organic material is at least one of polyimide, resin, epoxy, organosilicon polymer and acryl.
3. the material of the antireflection layer 33 may be an inorganic material, and the inorganic material is at least one of silicon oxide, silicon nitride, inorganic oxide and nitride.

In this embodiment, the material of the antireflection layer 33 is preferably an organic material, the organic material is preferably polyimide or organosilicon polymer, and the organosilicon polymer is preferably siloxane.

As shall be appreciated by those skilled in the art, when the liquid crystal display panel is operated outdoors, the strong ambient light forms reflected light at the interface of the black matrix 32 and the substrate 31 of the color film substrate 22, and the reflected light enters into eyes of human and thereby influences the outdoor visibility of the liquid crystal display panel.

Specifically, the black matrix 32 is mainly formed of carbon powders and polymers, the refractive index of the polymer is smaller than the refractive index of the carbon powder, and the refractive index of the substrate 31 is often between the refractive index of the polymer and the refractive index of the carbon powder. For example, when the substrate 31 is glass, the refractive index of the substrate 31 is 1.52 which is between the refractive index real part 1.4 of the polymer and the refractive index real part 2.0 of the carbon powder. In a mixed system of carbon powders and polymers, the equivalent refractive index increases as the content of the carbon powders increases so that the difference in refractive indexes between the substrate 31 and the black matrix 32 are relatively large and a relatively strong reflective effect is generated between the interfaces of the substrate 31 and the black matrix 32.

In order to reduce the reflected light, the antireflection layer 33 is disposed between the substrate 31 and the black matrix 32 in this embodiment, and the refractive index of the antireflection layer 33 is smaller than the refractive index of the black matrix 32 and greater than the refractive index of the substrate 31. Then, values of the thickness and the refractive index of the antireflection layer 33 are optimized by experiments or simulation software so that the reflectance of the incident light at the viewing side is reduced, i.e., even if there is light that enters into eyes of human after being reflected, the light is reduced as much as possible, thereby improving the visibility of the liquid crystal display panel.

In this embodiment, when the thickness of the antireflection layer 33 changes from 10 nm to 150 nm, the preferred thickness of the antireflection layer of which the refractive index ranges from 1.6 to 2.0 is greater than 100 nm and less than or equal to 150 nm, and is preferably between 110 nm and 120 nm; and the preferred thickness of the antireflection layer of which the refractive index ranges from 1.5 to 2.4 is less than 60 nm and greater than or equal to 10 nm, and is preferably between 20 nm and 40 nm.

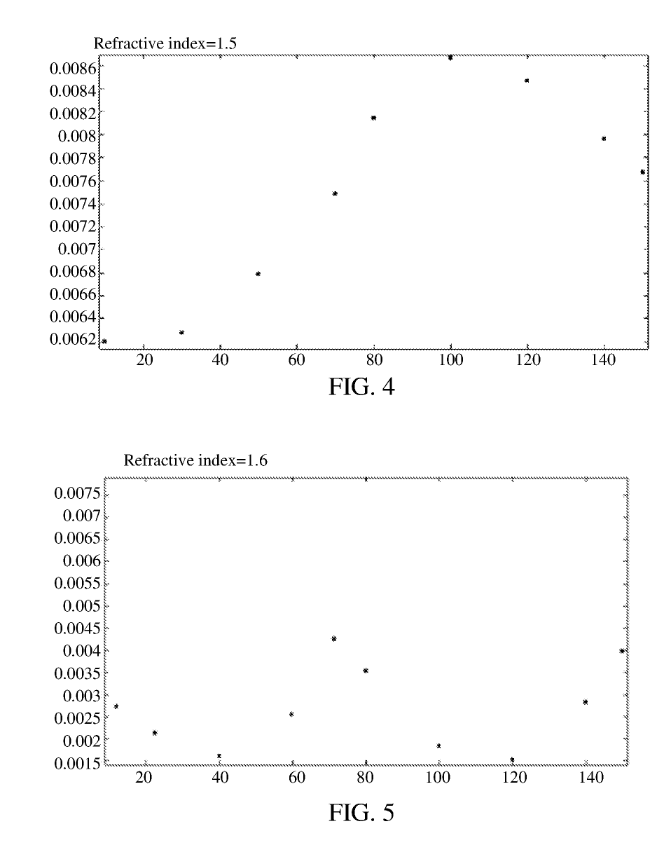

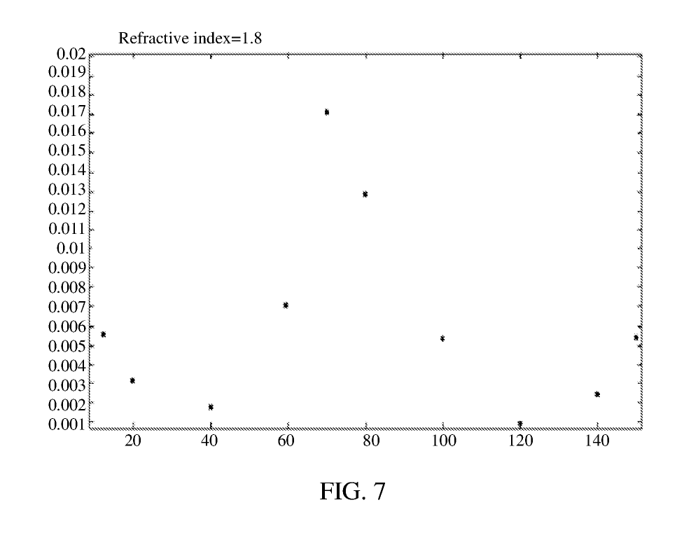

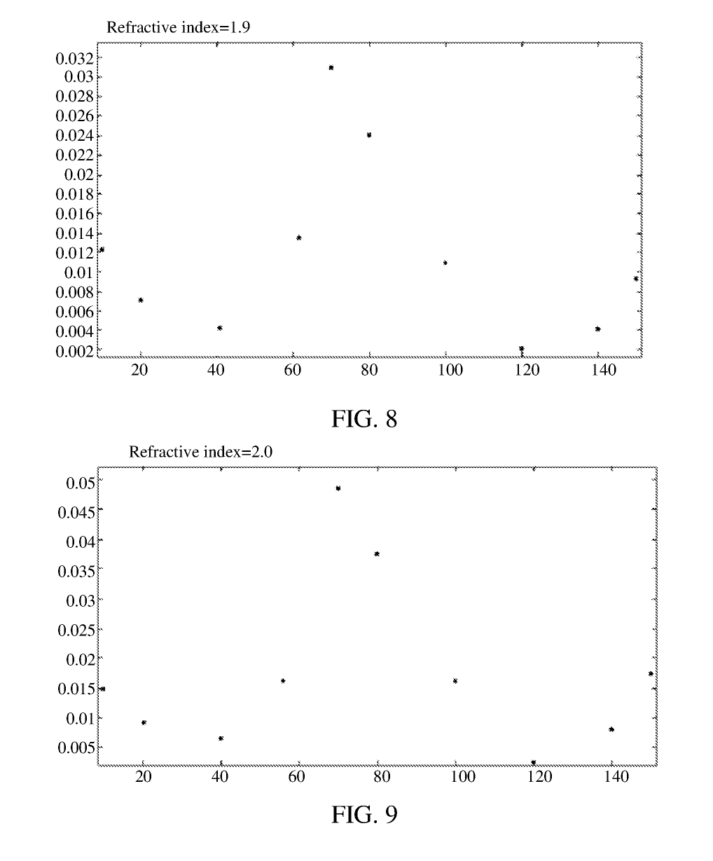

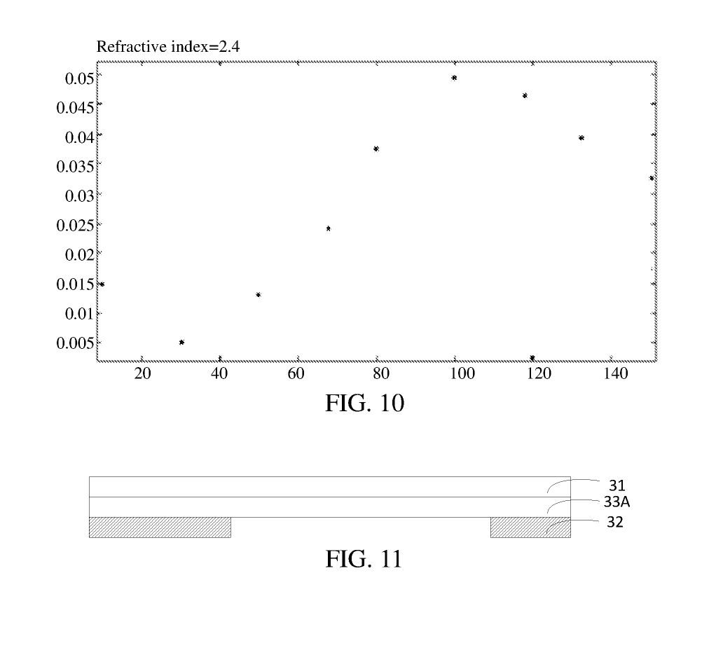

Referring to FIG. 4 to FIG. 10 together, FIG. 4 to FIG. 10 are a schematic views illustrating relationships between the thickness of the antireflection layer and energy of the reflected light when the refractive indexes of the antireflection layer are respectively 1.5, 1.6, 1.7, 1.8, 1.9, 2.0 and 2.4. As shown in FIG. 4 to FIG. 10, the horizontal coordinate represents the thickness of the antireflection layer, and the vertical coordinate represents the energy of the reflected light.

When the refractive indexes of the antireflection layer are respectively 1.5 and 2.4, waveforms of the schematic views illustrating the relationships of the two cases are relatively similar. When the value of the thickness of the antireflection layer 33 changes from 10 nm to 100 nm, the energy of the reflected light increases generally as the thickness of the antireflection layer increases; and when the value of the thickness of the antireflection layer 33 changes from 100 nm to 150 nm, the energy of the reflected light decreases generally as the thickness of the antireflection layer increases. The optimal thickness of the antireflection layer is between 20 nm and 40 nm.

When the refractive indexes of the antireflection layer are respectively 1.6, 1.7, 1.8, 1.9 and 2.0, waveforms of the schematic views illustrating the relationships of these five cases are relatively similar. When the thickness of the antireflection layer 33 changes from 10 nm to 150 nm, the energy of the reflected light is presented in the form of two parabolas. That is, when the value of the thickness of the antireflection layer is between 10 nm and 60 nm or between 100 nm and 150 nm, the energy of the reflected light is relatively small and can satisfy actual requirements. The optimal thickness of the antireflection layer is between 20 nm and 40 nm or between 110 nm and 120 nm.

Additionally, FIG. 4 to FIG. 10 are tested based on the fact that the material of the substrate 31 is glass, and the material of the antireflection layer 33 is organosilicon polymer, e.g., siloxane.

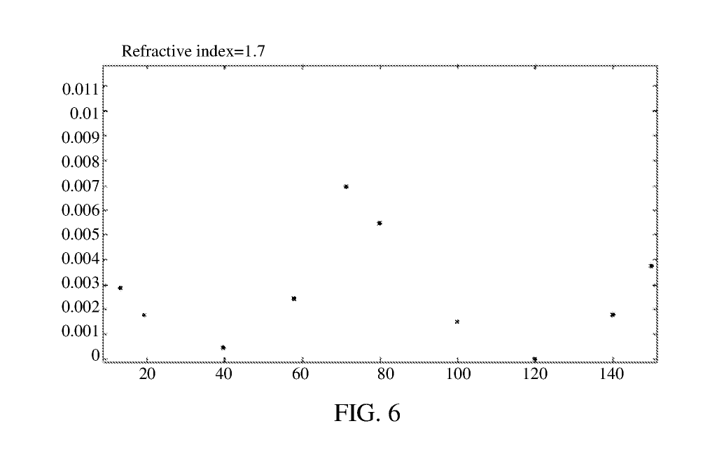

As shall be appreciated by those skilled in the art, when other materials are selected as the material of the antireflection layer 33, graphs similar to FIG. 4 to FIG. 10 will also be obtained, and respective thicknesses can be selected according to the refractive indexes that the material can reach. For example, when the material of the antireflection layer 33 is silicon nitride, the refractive index thereof is generally smaller than 1.7, and an appropriate thickness is selected according to FIG. 6.

FIG. 11 is a schematic structural view of a second embodiment of the color film substrate comprised in the liquid crystal display panel shown in FIG. 2. As shown in FIG. 11, the color film substrate of FIG. 11 differs from the color film substrate of FIG. 3 in that: an antireflection layer 33A of FIG. 11 has a pattern different from that of the antireflection layer 33 of FIG. 3, and the antireflection layer 33A of FIG. 11 covers the substrate 31, so the color of the antireflection layer 33A needs to be set to be transparent.

That is, the material of the antireflection layer 33A can only be the aforesaid organic material or inorganic material, and cannot be another black matrix.

Furthermore, other technical features of FIG. 11 are similar to these of FIG. 3, and thus will not be further described herein for simplification.

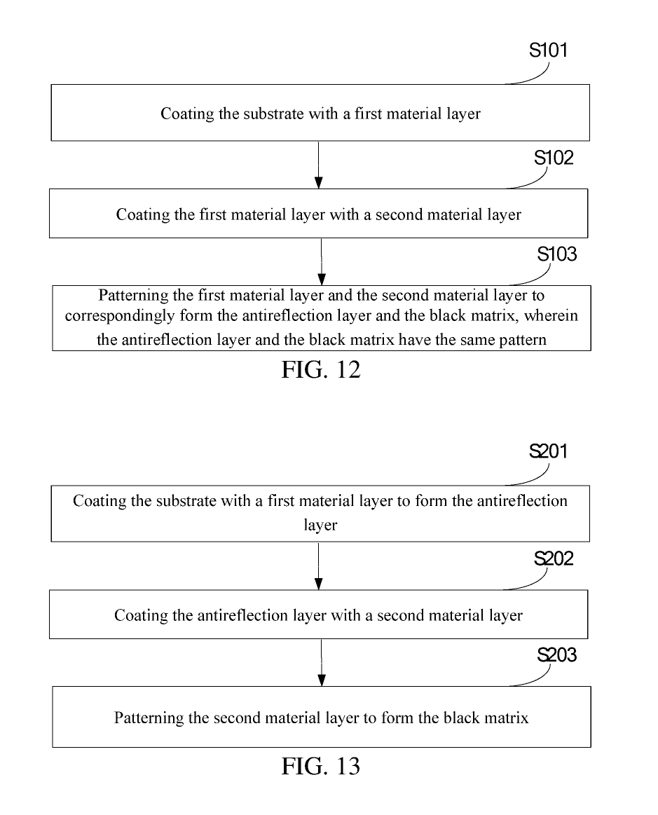

FIG. 12 is a flowchart diagram of a method for manufacturing a color film substrate according to a first embodiment of the present disclosure. As shown in FIG. 12, the method comprises:

Block S101: coating the substrate with a first material layer.

In the block S101, the first material layer is used for forming the antireflection layer, and the material of the first material layer may be another black matrix that belongs to the same category as a black matrix to be formed subsequently and has a refractive index lower than that of the black matrix to be formed subsequently. Moreover, the first material layer may also be an organic material, and the organic material is at least one of polyimide, resin, epoxy, organosilicon polymer and acryl; or the first material layer may also be an inorganic material, and the inorganic material is at least one of silicon oxide, silicon nitride, inorganic oxide and nitride.

The first material layer may be transparent or may not be transparent.

Block 102: coating the first material layer with a second material layer.

In the block 102, the second material layer is used for forming the black matrix, and the second material layer is not transparent.

Block 103: patterning the first material layer and the second material layer to correspondingly form the antireflection layer and the black matrix, wherein the antireflection layer and the black matrix have the same pattern.

In the block 103, the block of patterning the first material layer and the second material layer to correspondingly form the antireflection layer and the black matrix is specifically as follows: the second material layer is coated with a photoresist layer, the photoresist layer is exposed and developed via a photomask, and the developed photoresist layer, the second material layer and the first material layer are etched; and then the photoresist layer, the second material layer and the first material layer that have been etched are separated to form the antireflection layer and the black matrix.

The refractive index of the antireflection layer is about 1.6˜2.0, the thickness of the antireflection layer is greater than 100 nm; and preferably, the thickness of the antireflection layer is 100 nm to 150 nm. In addition, the refractive index of the antireflection layer is about 1.5˜2.4, the thickness of the antireflection layer is less than 60 nm, and preferably, the thickness of the antireflection layer is 10 nm to 60 nm. As shall be appreciated by those skilled in the art, in this embodiment, the antireflection layer and the black matrix can be realized without the need of adopting the solution involving coating for two times each of which requires exposing and developing, so the production cost of the color film substrate can be reduced while reducing the reflectance of the liquid crystal display panel.

FIG. 13 is a flowchart diagram of a method for manufacturing a color film substrate according to a second embodiment of the present disclosure. As shown in FIG. 13, the method comprises:

Block S201: coating the substrate with a first material layer to form the antireflection layer.

In the block S201, the first material layer is used for forming the antireflection layer, and the material of the first material layer may be an organic material, and the organic material is at least one of polyimide, resin, epoxy, organosilicon polymer and acryl; or the first material layer may also be an inorganic material, and the inorganic material is at least one of silicon oxide, silicon nitride, inorganic oxide and nitride.

The first material layer is transparent.

The refractive index of the first material layer, i.e., the antireflection layer, is about 1.6 to 2.0, the thickness of the first material layer is greater than 100 nm; or the refractive index of the first material layer, i.e., the antireflection layer, is about 1.5 to 2.4, and the thickness of the first material layer is smaller than 60 nm.

Preferably, the thickness of the first material layer is 100 nm to 150 nm or 10 nm to 60 nm.

Block S202: coating the antireflection layer with a second material layer.

In the block S202, the second material layer is used for forming the black matrix, and the second material layer is not transparent.

Block S203: patterning the second material layer to form the black matrix.

In the block S203, the block of patterning the second material layer to form the black matrix is specifically as follows: the second material layer is coated with a photoresist layer, the photoresist layer is exposed and developed via a photomask, and the developed photoresist layer and the second material layer are etched; and then the photoresist layer and the second material layer that have been etched are separated to form the black matrix.

As shall be appreciated by those skilled in the art, in this embodiment, the antireflection layer can be realized simply by coating for one time and the black matrix can be realized by coating, exposing and developing for one time, so the production cost of the color film substrate can be remarkably reduced while reducing the reflectance of the liquid crystal display panel.

Benefits of the present disclosure are as follows: the color film substrate and the method for manufacturing the same as well as the liquid crystal display panel of the present disclosure can decrease the reflectance of the liquid crystal display panel in a simpler manner and at a lower cost and thereby improve the display quality of the liquid crystal display panel under the environment of strong light by providing the antireflection layer between the black matrix and the substrate of the color film substrate, wherein the refractive index of the antireflection layer is about 1.6˜2.0 and the thickness of the antireflection layer is greater than 100 nm; or the refractive index of the antireflection layer is about 1.5˜2.4 and the thickness of the antireflection layer is less than 60 nm.

What described above are only the embodiments of the present disclosure, but are not intended to limit the scope of the present disclosure. Any equivalent structures or equivalent process flow modifications that are made according to the specification and the attached drawings of the present disclosure, or any direct or indirect applications of the present disclosure in other related technical fields shall all be covered within the scope of the present disclosure.

What is claimed is:

1. A color film substrate, comprising: a substrate, a black matrix disposed on the substrate, and an antireflection layer disposed between the substrate and the black matrix;
wherein a refractive index of the antireflection layer is about 1.6˜2.0, a thickness of the antireflection layer is greater than 100 nm; or
the refractive index of the antireflection layer is about 1.5˜2.4, and the thickness of the antireflection layer is less than 60 nm.

2. The color film substrate according to claim 1, wherein the refractive index of the antireflection layer satisfies the following equation:
max(G, (G*M)0.5−0.2)<C<min((G*M)0.5+0.2,M)
wherein G is a refractive index of the substrate, M is a refractive index of the black matrix, and C is the refractive index of the antireflection layer.

3. The color film substrate according to claim 1, wherein the antireflection layer has the same composition as the black matrix, and the composition at least comprises carbon powders and polymers, and the content of the carbon powders in the antireflection layer is smaller than the content of the carbon powders in the black matrix.

4. The color film substrate according to claim 1, wherein a material of the antireflection layer is an organic material, and the organic material is at least one of polyimide, resin, epoxy, organosilicon polymer and acryl.

5. The color film substrate according to claim 1, wherein a material of the antireflection layer is an inorganic material, and the inorganic material is at least one of silicon oxide, silicon nitride, inorganic oxide and nitride.

6. The color film substrate according to claim 1, wherein the thickness of the antireflection layer is about 100˜150 nm or about 10˜60 nm.

7. A liquid crystal display (LCD) panel, comprising a color film substrate, an array substrate disposed opposite to the color film substrate and a liquid crystal layer interposed between the color film substrate and the array substrate;
the color film substrate comprising: a substrate, a black matrix disposed on the substrate, and an antireflection layer disposed between the substrate and the black matrix;
wherein a refractive index of the antireflection layer is about 1.6˜2.0, a thickness of the antireflection layer is greater than 100 nm; or
the refractive index of the antireflection layer is about 1.5˜2.4, and the thickness of the antireflection layer is less than 60 nm.

8. The liquid crystal display panel according to claim 7, wherein the refractive index of the antireflection layer satisfies the following equation:
max(G, (G*M)0.5−0.2)<C<min((G*M)0.5+0.2,M)
wherein G is a refractive index of the substrate, M is a refractive index of the black matrix, and C is the refractive index of the antireflection layer.

9. The liquid crystal display panel according to claim 7, wherein the antireflection layer has the same composition as the black matrix, and the composition at least comprises carbon powders and polymers, and the content of the carbon powders in the antireflection layer is smaller than the content of the carbon powders in the black matrix.

10. The liquid crystal display panel according to claim 7, wherein a material of the antireflection layer is an organic material, and the organic material is at least one of polyimide, resin, epoxy, organosilicon polymer and acryl.

11. The liquid crystal display panel according to claim 7, wherein a material of the antireflection layer is an inorganic material, and the inorganic material is at least one of silicon oxide, silicon nitride, inorganic oxide and nitride.

12. The liquid crystal display panel according to claim 7, wherein the thickness of the antireflection layer is about 100˜150 nm or about 10˜60 nm.

13. A method for manufacturing a color film substrate, comprising:
forming an antireflection layer and a black matrix sequentially on a substrate;
wherein a refractive index of the antireflection layer is about 1.6˜2.0, and a thickness of the antireflection layer is greater than 100 nm; or
the refractive index of the antireflection layer is about 1.5˜2.4, and the thickness of the antireflection layer is less than 60 nm.

14. The manufacturing method according to claim 13, wherein the forming the antireflection layer and the black matrix sequentially on the substrate comprises:
coating the substrate with a first material layer;
coating the first material layer with a second material layer;
patterning the first material layer and the second material layer to correspondingly form the antireflection layer and the black matrix,
wherein the antireflection layer and the black matrix have the same pattern.

15. The manufacturing method according to claim 13, wherein the forming the antireflection layer and the black matrix sequentially on the substrate comprises:
coating the substrate with a first material layer to form the antireflection layer;
coating the antireflection layer with a second material layer; and
patterning the second material layer to form the black matrix.
